(19) United States
(12) Patent Application Publication
(10) Pub. No.: US 2021/0142147 A1
(43) Pub. Date: May 13, 2021

(54) PORTABLE INFORMATION TERMINAL AND PROBLEM SOLVING SYSTEM

(71) Applicant: SEMICONDUCTOR ENERGY LABORATORY CO., LTD., Atsugi-shi, Kanagawa-ken (JP)

(72) Inventor: Shunpei YAMAZAKI, Setagaya, Tokyo (JP)

(21) Appl. No.: 16/620,768

(22) PCT Filed: Jun. 19, 2018
(86) PCT No.: PCT/IB2018/054485

§ 371 Date: Dec. 9, 2019

(30) Foreign Application Priority Data
Jun. 27, 2017 (JP) 2017-125686
Aug. 11, 2017 (JP) 2017-156247

(51) Int. Cl. G06N 3/04; G06N 3/08; G06N 3/063; H01L 29/786

(52) U.S. Cl. CPC G06N 3/0454; H01L 29/7869; G06N 3/0635; G06N 3/08

(57) ABSTRACT

A portable information terminal and a problem solving system each with a novel configuration are provided.

The portable information terminal includes an input operation portion, a signal transmitting/receiving portion, and an output operation portion. The input operation portion includes a first neural network circuit that generates first data on the basis of input information. The first neural network circuit has a function of learning a plurality of pieces of input information as learning data. The signal transmitting/receiving portion has a function of transmitting the first data to a data server and a function of receiving information data from the data server in response to the first data. The output operation portion includes a second neural network circuit that learns the information data as learning data. The second neural network circuit has a function of generating output information on the basis of the learning.

### TECHNICAL FIELD

One embodiment of the present invention relates to a portable information terminal and a problem solving system.

### BACKGROUND ART

The amount of data generated in the world has been increasing day by day. An information search service using a data server for storing data has been spread. Such an information search service can be used outdoors owing to data communication or the like using a portable information terminal. For example, an information search system using data communication between a portable information terminal and a data server is disclosed in Patent Document 1.

### PRIOR ART DOCUMENT

### Patent Document

[Patent Document 1] PCT International Publication No. 2011/096945

### SUMMARY OF THE INVENTION

### Problems to be Solved by the Invention

An answer obtained by a portable information terminal or the like in response to an input of a problem often provides a single meaning, that is, other meanings or interpretations cannot be considered. A system from which a single-meaning answer to a problem can be obtained is highly convenient for a user; however, the system might not be able to deal with the case of considering answers to an unknown problem, for example, and thus might have poor versatility. Alternatively, in the case where an answer is found to be wrong later, it might be difficult to follow the route and the like for deriving the answer and correct the answer.

An object of one embodiment of the present invention is to provide a novel portable information terminal and problem solving system. Another object of one embodiment of the present invention is to provide a novel portable information terminal and problem solving system from which a versatile answer to a problem can be obtained. Another object of one embodiment of the present invention is to provide a novel portable information terminal and problem solving system that can follow the process of deriving the obtained answer to a problem and correct the answer.

### Means for Solving the Problems

One embodiment of the present invention is a portable information terminal including an input operation portion, a signal transmitting/receiving portion, and an output operation portion. The input operation portion includes a first neural network circuit that generates first data on the basis of input information; the first neural network circuit has a function of learning a plurality of pieces of input information as learning data; the signal transmitting/receiving portion has a function of transmitting the first data to a data server and a function of receiving information data from the data server in response to the first data; the output operation portion includes a second neural network circuit that learns the information data as learning data; and the second neural network circuit has a function of generating output information on the basis of the learning.

In the portable information terminal of one embodiment of the present invention, it is preferable that the input operation portion include a judgement circuit, the judgement circuit have a function of storing judgement data, and the input operation portion have a function of comparing the first data and the judgement data and a function of stopping a function of the signal transmitting/receiving portion in accordance with a result of the comparison.

In the portable information terminal of one embodiment of the present invention, it is preferable that the first neural network circuit and the second neural network circuit each include a product-sum operation circuit.

In the portable information terminal of one embodiment of the present invention, it is preferable that the product-sum operation circuit include a memory element, the memory element include a transistor, and the transistor include an oxide semiconductor in a semiconductor layer including a channel formation region.

It is preferable that one embodiment of the present invention be a problem solving system including a portable information terminal including an input operation portion, a signal transmitting/receiving portion, and an output operation portion, and a data server that stores information data. The input operation portion includes a first neural network circuit that generates first data on the basis of input information; the first neural network circuit has a function of learning a plurality of pieces of input information as learning data; the signal transmitting/receiving portion has a function of transmitting the first data to the data server and a function of receiving information data from the data server in response to the first data; the output operation portion includes a second neural network circuit that learns the information data as learning data; and the second neural network circuit has a function of generating output information on the basis of the learning.

In the problem solving system of one embodiment of the present invention, it is preferable that the input operation portion include a judgement circuit, the judgement circuit have a function of storing judgement data, and the input operation portion have a function of comparing the first data and the judgement data and a function of stopping a function of the signal transmitting/receiving portion in accordance with a result of the comparison.

In the problem solving system of one embodiment of the present invention, it is preferable that the first neural network circuit and the second neural network circuit each include a product-sum operation circuit.

In the problem solving system of one embodiment of the present invention, it is preferable that the product-sum operation circuit include a memory element, the memory element include a transistor, and the transistor include an oxide semiconductor in a semiconductor layer including a channel formation region.

Note that other embodiments of the present invention will be shown in the following “Mode for Carrying out the Invention” and the “drawings”.

### Effect of the Invention

One embodiment of the present invention can provide a novel portable information terminal and problem solving system. Another embodiment of the present invention can provide a novel portable information terminal and problem solving system from which a versatile answer to a problem can be obtained. Another embodiment of the present invention can provide a novel portable information terminal and problem solving system which can follow the process of deriving the obtained answer to a problem and correct the answer.

### BRIEF DESCRIPTION OF DRAWINGS

[FIG. 1] A diagram for describing a configuration of one embodiment of the present invention.

[FIG. 2] A diagram for describing a configuration of one embodiment of the present invention.

[FIG. 3] Diagrams for describing configurations of one embodiment of the present invention.

[FIG. 4] A diagram for describing a configuration of one embodiment of the present invention.

[FIG. 5] A diagram for describing a configuration of one embodiment of the present invention.

[FIG. 6] Diagrams for describing a configuration of one embodiment of the present invention.

[FIG. 7] Diagrams for describing a configuration of one embodiment of the present invention.

[FIG. 8] A diagram for describing a configuration of one embodiment of the present invention.

[FIG. 9] A diagram for describing a configuration of one embodiment of the present invention.

[FIG. 10] Diagrams for describing a configuration of one embodiment of the present invention.

[FIG. 11] Diagrams illustrating a configuration example of a neural network.

[FIG. 12] A diagram illustrating a configuration example of a semiconductor device.

[FIG. 13] A diagram illustrating configuration examples of memory cells.

[FIG. 14] A diagram illustrating a configuration example of an offset circuit.

[FIG. 15] A timing chart.

[FIG. 16] Diagrams each illustrating an example of a portable information terminal.

### MODE FOR CARRYING OUT THE INVENTION

Hereinafter, embodiments of the present invention will be described with reference to drawings. However, the embodiments of the present invention can be implemented with many different modes, and it will be readily appreciated by those skilled in the art that modes and details thereof can be changed in various ways without departing from the spirit and scope thereof. Thus, the present invention should not be interpreted as being limited to the following description.

### Embodiment 1

<Configuration Example>

FIG. 1 is a conceptual view for describing a configuration example of a problem solving system that uses a portable information terminal.

A problem solving system 10 illustrated in FIG. 1 can be roughly divided into a portable information terminal 20 and a data server 30. The portable information terminal 20 includes, as main components, an input portion 21, an input operation portion 22, a signal transmitting/receiving portion 23, an output operation portion 24, and an output portion 25. The input operation portion 22 includes a neural network circuit 26 (a first neural network circuit, NN1 in the figure). The output operation portion 24 includes a neural network circuit 27 (a second neural network circuit, NN2 in the figure).

In FIG. 1, signals indicated by arrows are transmitted in the following order: the input portion 21, the input operation portion 22, the signal transmitting/receiving portion 23, the data server 30, the output operation portion 24, and the output portion 25. Note that in this specification, a signal can be replaced with data or information as appropriate.

The input portion 21 has a function of enabling a user to input information. Specific examples of the input portion 21 are a touch panel, a microphone, and a camera.

Input information Dᵢₙ is data to be output from the input portion 21 to the input operation portion 22. The input information Dᵢₙ is information input by a user. For example, in the case where the input portion 21 is a touch panel, the input information Dᵢₙ is information obtained by text input with the touch panel operation. Alternatively, in the case where the input portion 21 is a microphone, the input information Dᵢₙ is information obtained by sound input by a user. Alternatively, in the case where the input portion 21 is a camera, the input information Dᵢₙ is information obtained by image processing of imaging data.

The input operation portion 22 includes the neural network circuit 26 that generates data D₁ on the basis of the input information Dᵢₙ. The input information Dᵢₙ is data to be learned by the neural network circuit 26. Furthermore, the input information Dᵢₙ is data to be inferred by the neural network circuit 26, and the neural network circuit 26 can output the data D₁ in response to the input information Dᵢₙ by the inference.

Note that the learning in the neural network circuit 26 can also be performed by the supply of a weight coefficient obtained by a neural network circuit additionally prepared for learning. In this case, weight coefficients that have been learned can be generated in advance in the following manner: teacher data obtained by adding information of a superordinate concept or a subordinate concept as a label to data stored in the data server is generated in the neural network circuit for learning, and then the weight coefficients of the neural network circuit for leaning are updated. Note that learning in the neural network circuit 27 to be described later can also be performed in a similar manner.

The data D₁ is data output from the input operation portion to the signal transmitting/receiving portion 23 and from the signal transmitting/receiving portion 23 to the data server 30. The data D₁ is information obtained by inference in the neural network circuit 26. Accordingly, a concept itself recognized by a user, information of a superordinate concept or a subordinate concept obtained by inference, or a concept that is not recognized by a user is included in some cases. That is, the data D₁ is converted into data including not only the original input information Dᵢₙ but also a plurality of pieces of information related to the input information Dᵢₙ.

The signal transmitting/receiving portion 23 has a function of transmitting the data D₁ to the data server 30 and a function of receiving a plurality of pieces of information data D_{info} from the data server 30. The signal transmitting/receiving portion 23 can be formed of an antenna for transmitting and receiving a signal, a circuit for encoding and decoding, an interface circuit, and the like.

The data server 30 includes a database for generating the information data D_{info} on the basis of the data D₁. The data server 30 is also referred to as a cloud in some cases. The data included in the data server 30 is data stored in a data server that can be accessed via a network. Alternatively, the data included in the data server 30 can also be referred to as data generated all over the world and accumulated day by day, what is called big data. The data server 30 collects information on the data D₁ and a plurality of pieces of information related to the data D₁, and transmits them to the signal transmitting/receiving portion 23 as the plurality of pieces of information data D_{info}.

The information data D_{info} is data output from the data server 30 to the signal transmitting/receiving portion 23 and from the signal transmitting/receiving portion 23 to the output operation portion 24.

The output operation portion 24 includes the neural network circuit 27 that generates output information Dₒᵤₜ on the basis of the information data D_{info}. The information data D_{info} is data to be learned by the neural network circuit 27. In addition, the information data D_{info} is data to be inferred by the neural network circuit 27, and the neural network circuit 27 can output the output information Dₒᵤₜ in response to the information data D_{info} by the inference. Note that a configuration may be employed in which the data D₁ and the information data D_{info} are input to the neural network circuit 27 for learning or inference.

The output information Dₒᵤₜ is data to be output from the output operation portion 24 to the output portion 25. The output information Dₒᵤₜ is information obtained by inference in the neural network circuit 27. Accordingly, a concept itself recognized by a user, information of a superordinate concept or a subordinate concept obtained by inference, or a concept that is not recognized by a user is included in some cases. That is, the output information Dₒᵤₜ is data related to, not just a piece of information, but a plurality of pieces of information such as a concept itself that is recognized by a user, information of a superordinate concept or a subordinate concept obtained by inference, and a concept that is not recognized by a user.

The configuration of the problem solving system 10 is not limited to the configuration of FIG. 1, and the configuration of FIG. 2 may be employed. FIG. 2 illustrates a configuration in which the output information Dₒᵤₜ as well as the input information Dᵢₙ is used as data to be learned or inferred by the neural network circuit 26, and the input information Dᵢₙ as well as the information data D_{info} is used as data to be learned or inferred by the neural network circuit 27.

With the configuration of FIG. 2, when a conclusion for an input (inquiry) is obtained, that is, when the output information Dₒᵤₜ is output, learning or inference can be performed in the neural network circuit 26 to which the input information Dᵢₙ is input, with the use of the output information Dₒᵤₜ. Thus, the weight coefficients of the neural network circuit 26 in the process of conclusion can be updated using data that has reached a conclusion.

FIG. 2 also illustrates a configuration in which learning or inference is performed in the neural network circuit 27 for obtaining an answer, with the use of the input information Dᵢₙ.

Note that the neural network circuit 26 and the neural network circuit 27 each include a product-sum operation circuit that can perform product-sum operation processing. The product-sum operation circuit includes a memory circuit for storing weight data. A memory element included in the memory circuit includes a transistor and a capacitor, and the transistor is preferably a transistor including an oxide semiconductor in a semiconductor layer including a channel formation region (hereinafter, an OS transistor). An OS transistor has an extremely low leakage current that flows in an off state. Therefore, by utilizing the characteristics of an OS transistor that enables charge retention by being turned off, data can be stored. The configurations of the neural network circuits will be described in detail in Embodiment 2.

In the problem solving system 10 illustrated in FIG. 1, more appropriate answer or decision can be obtained in the case where a user inputs an inquiry or determination (inquiry data) to the input portion 21 and obtains an answer to the inquiry or a decision for the determination (answer data) from the output portion 25.

For example, in the configuration where a user inputs inquiry data to a portable information terminal and obtains answer data from the data server, the answer data is determined to provide a single meaning in some cases (FIG. 3(A)). In such a case, the user uses the obtained answer data as it is, which might lead to loss of opportunity to distinguish right from wrong or search more appropriate answer data.

On the other hand, the problem solving system 10 of one embodiment of the present invention, in the case where a user inputs inquiry data to the portable information terminal 20 and obtains answer data from the data server 30, can have a configuration in which related information is once generated in the neural network circuit 26 on the basis of the inquiry data, and then a plurality of pieces of information data are collected in the data server 30 on the basis of the related information. Then, the steps of performing inference on the basis of the plurality of pieces of information data collected in the neural network circuit 27 and generating answer data can be conducted (FIG. 3(B)). Thus, the user can use the obtained answer data as it is, and furthermore, can search more appropriate answer data by combining the user's determination and the answer data. Alternatively, the user can search more appropriate answer data using the answer data as advice.

The schematic view of the problem solving system in FIG. 3(B) can be described with reference to a flow chart shown in FIG. 4.

In Step S01, learning or inference is performed in the neural network circuit 26 (NN1) using the input of the inquiry data (Dᵢₙ). Through the step, related information can be output on the basis of the inquiry data.

In Step S02, the neural network circuit 26 (NN1) performs inference and generates the related information (D₁). Through the step, the related information (D₁) can be information including a concept itself that is recognized by a user, information of a superordinate concept or a subordinate concept obtained by inference, or a concept that is not recognized by a user.

In Step S03, information (D_{info}) based on the related information (D₁) is collected in the data server 30, and learning or inference is performed in the neural network circuit 27 (NN2) with the use of a plurality of pieces of information obtained by the collection. Through the step, the neural network circuit 27 can perform learning or inference on the basis of the information including a concept itself that is recognized by a user, information of a superordinate concept or a subordinate concept obtained by inference, or a concept that is not recognized by a user.

In Step S04, the neural network circuit 27 (NN2) performs inference and generates answer data (Dₒᵤₜ). Through the step, the information including a concept itself that is recognized by a user, information of a superordinate concept or a subordinate concept obtained by inference, or a concept that is not recognized by a user can be obtained as the answer data.

An example of more detailed operation of the problem solving system 10 illustrated in FIG. 1 is described with reference to a flow chart in FIG. 5 and schematic views illustrated in FIG. 6 and FIG. 7 corresponding to the steps in the flow chart.

In Step S11 (FIG. 5 and FIG 6(A)), the input information Dᵢₙ is obtained

Next, in Step S12 (FIG. 5 and FIG. 6(B)), the neural network circuit 26 (NN1) performs learning.

Next, in Step S13 (FIG. 5 and FIG. 6(B)), the neural network circuit 26 (NN1) performs inference and generates the data D₁.

Next, in Step S14 (FIG. 5 and FIG 7(A)), the information data D_{info} that responds to the data D₁ is obtained.

Next, in Step S15 (FIG. 5 and FIG. 7(A)), the neural network circuit 27 (NN2) performs learning.

Next, in Step S16 (FIG 5 and FIG. 7(B)), the neural network circuit 27 (NN2) performs inference and generates the output information

As described above, the problem solving system 10 of one embodiment of the present invention can have a configuration in which the data D₁ is generated in the neural network circuit 26 on the basis of the input information Dᵢₙ and the plurality of pieces of information data pinto are obtained in the data server 30 on the basis of the data D₁. Then, the steps of performing learning or inference in the neural network circuit 27 on the basis of the plurality of pieces of information data D_{info} that are obtained and generating the output information Dₒᵤₜ can be conducted. Thus, the user can search a more appropriate answer or make more appropriate determination by combining the user's determination and the output information Dₒᵤₜ.

<Modification Example>

As a modification example, FIG. 8 illustrates a block diagram of a problem solving system that is different from that of FIG. 1. A problem solving system 10A illustrated in FIG. 8 is different from the problem solving system 10 illustrated in FIG. 1 in that the input operation portion 22 includes a judgement circuit 28.

The judgement circuit 28 has a function of storing judgement data D_{judge} input from the outside. In addition, the judgement circuit 28 compares the stored judgement data D_{judge} and the data D₁ input from the input operation portion 22, and switches logic of a signal S_{EN} in accordance with whether the data match or not. The signal S_{EN} is a signal for switching whether to stop the function of the signal transmitting/receiving portion 23 or not by switching the logic. Note that data matching includes substantial matching or concept matching.

An example of more detailed operation of the problem solving system 10A illustrated in FIG. 8 is described with reference to a flow chart in FIG. 9 and schematic views illustrated in FIG. 10 each corresponding to the step in the flow chart. Note that in the description with FIG. 9 and FIG. 10, the same description as the above description for the problem solving system 10 with FIG. 5 to FIG. 7 is omitted, and only different points are described.

In Step S17 (FIG. 9, FIG. 10(A)), whether the data D₁ and the judgement data D_{judge} match or not is judged. In the case where the data do not match, the operation proceeds to Step S14. In the case where the data match, the operation proceeds to Step S18. Through the step, the logic of the signal S_{EN} is switched, that is, whether to stop the function of the signal transmitting/receiving portion 23 or not is determined.

Next, in Step S18 (FIG. 9, FIG. 10(B)), the logic of the signal S_{EN} is switched. Through the step, the function of the signal transmitting/receiving portion 23 can be stopped.

As described above, in the problem solving system 10A of one embodiment of the present invention, inference in the neural network circuit 26 can inhibit generation of inappropriate data D₁. Since the judgement data D_{judge} can be set by a user, obtaining wrong output information Dₒᵤₜ (e.g., inappropriate information that violates the law) by inference in the neural network circuit 26 can be prevented.

### Embodiment 2

In this embodiment, a structure example of a semiconductor device that can be used in the neural network circuits described in the above embodiment is described.

Note that in this specification, a semiconductor device refers to a device that can function by utilizing semiconductor characteristics. That is, a neural network circuit including a transistor that utilizes semiconductor characteristics is a semiconductor device.

As illustrated in FIG. 11(A), a neural network NN can be formed of an input layer IL, an output layer OL, and a middle layer (hidden layer) HL. The input layer IL, the output layer OL, and the middle layer HL each include one or more neurons (units). Note that the middle layer HL may be one layer or two or more layers. A neural network including two or more middle layers HL can also be referred to as a DNN (deep neural network), and learning using a deep neural network can also be referred to as deep learning.

Input data is input to each neuron of the input layer IL, output signals of neurons in the previous layer or the subsequent layer are input to neurons of the middle layer HL, and output signals of neurons in the previous layer are input to neurons of the output layer OL. Note that each neuron may be connected to all the neurons in the previous and subsequent layers (full connection), or may be connected to some of the neurons.

FIG. 11(B) illustrates an example of an operation with the neurons. Here, a neuron N and two neurons in the previous layer which output signals to the neuron N are illustrated. An output x₁ of a neuron in the previous layer and an output x₂ of a neuron in the previous layer are input to the neuron N. Then, in the neuron N, a total sum x₁w₁+x₂w₂ of a multiplication result (x₁w₁) of the output x₁ and a weight w₁ and a multiplication result (x₂w₂) of the output x₂ and a weight w₂ is calculated, and then a bias b is added as necessary, so that the value a=x₁w₁+w₂w₂+b is obtained. Then, the value a is converted with an activation function h, and an output signal y=h(a) is output from the neuron N.

In this manner, the operation with the neurons includes the operation that sums the products of the outputs and the weights of the neurons in the previous layer, that is, the product-sum operation (x₁w₁+x₂w₂ in the above). This product-sum operation may be performed using a program on software or by hardware. In the case where the product-sum operation is performed by hardware, a product-sum operation circuit can be used. A digital circuit may be used or an analog circuit may be used as this product-sum operation circuit. In the case where an analog circuit is used as the product-sum operation circuit, the circuit scale of the product-sum operation circuit can be reduced, or higher processing speed and lower power consumption can be achieved by reduced frequency of access to a memory.

The product-sum operation circuit may be formed of a transistor including silicon (such as single crystal silicon) in a channel formation region (hereinafter also referred to as a Si transistor) or an OS transistor. An OS transistor is particularly preferable as a transistor included in a memory of the product-sum operation circuit because of its extremely low off-state current. Note that the product-sum operation circuit may be formed using both a Si transistor and an OS transistor. A configuration example of a semiconductor device having a function of the product-sum operation circuit is described below.

[Configuration Example of Semiconductor Device]

FIG. 12 illustrates a configuration example of a semiconductor device MAC having a function of performing an operation of the neural network. The semiconductor device MAC has a function of performing a product-sum operation of first data corresponding to the strength of connection (weight) between the neurons and second data corresponding to input data. Note that the first data and the second data can each be analog data or multilevel digital data (discrete data). The semiconductor device MAC also has a function of converting data obtained by the product-sum operation with the activation function.

The semiconductor device MAC includes a cell array CA, a current source circuit CS, a current mirror circuit CM, a circuit WDD, a circuit WLD, a circuit CLD, an offset circuit OFST, and an activation function circuit ACTV.

The cell array CA includes a plurality of memory cells MC and a plurality of memory cells MCref. In the configuration example illustrated in FIG. 12, the cell array CA includes the memory cells MC in in rows and n columns (memory cells MC[1, 1] to MC[m, n]) and the in memory cells MCref (MCref[1] to MCref[m]) (m and n are integers greater than or equal to 1). The memory cells MC have a function of storing the first data. In addition, the memory cells MCref have a function of storing reference data used for the product-sum operation. Note that the reference data can be analog data or multilevel digital data.

The memory cell MC[i, j] is connected to a wiring WL[i], a wiring RW[i], a wiring WD[j], and a wiring BL[j] (i is an integer greater than or equal to 1 and less than or equal to m, and j is an integer greater than or equal to 1 and less than or equal to n). In addition, the memory cell MCref[i] is connected to the wiring WL[i], the wiring RW[i], a wiring WDref, and a wiring BLref. Here, a current flowing between the memory cell MC[i, j] and the wiring BL[j] is denoted by I_{MC[i, j]}, and a current flowing between the memory cell MCref[i] and the wiring BLref is denoted by I_{MCref[i]}.

FIG. 13 illustrates a specific configuration example of the memory cell MC and the memory cell MCref. Although the memory cells MC[1, 1] and MC[2, 1] and the memory cells MCref[1] and MCref[2] are given as typical examples in FIG. 13, similar configurations can also be used for other memory cells MC and other memory cells MCref. The memory cells MC and the memory cells MCref each include transistors Tr11 and Tr12 and a capacitor C11. Here, the case where the transistor Tr11 and the transistor Tr12 are n-channel transistors is described.

In the memory cell MC, a gate of the transistor Tr11 is connected to the wiring WL, one of a source and a drain of the transistor Tr11 is connected to a gate of the transistor Tr12 and a first electrode of the capacitor C11, and the other of the source and the drain of the transistor Tr11 is connected to the wiring WD. One of a source and a drain of the transistor Tr12 is connected to the wiring BL, and the other of the source and the drain thereof is connected to a wiring VR. A second electrode of the capacitor C11 is connected to the wiring RW. The wiring VR has a function of supplying a predetermined potential. An example in which a low power source potential (e.g., a ground potential) is supplied from the wiring VR is described below.

A node connected to the one of the source and the drain of the transistor Tr11, the gate of the transistor Tr12, and the first electrode of the capacitor C11 is referred to as a node NM. The nodes NM included in the memory cells MC[1, 1] and MC[2, 1] are referred to as nodes NM[1, 1] and NM[2, 1], respectively.

The memory cells MCref have a configuration similar to that of the memory cell MC. However, the memory cells MCref are connected to the wiring WDref instead of the wiring WD and connected to a wiring BLref instead of the wiring BL. A node in the memory cell MCref[1] and a node in the memory cell MCref[2], each of which is connected to one of the source and the drain of the transistor Tr11, the gate of the transistor Tr12, and the first electrode of the capacitor C11, are referred to as a node NMref[1] and a node NMref[2], respectively.

The node NM and the node NMref function as holding nodes of the memory cell MC and the memory cell MCref, respectively. The first data is held in the node NM and the reference data is held in the node NMref. Furthermore, currents I_{MC[1, 1]} and I_{MC[2, 1]} flow from the wiring BL[1] to the transistors Tr12 of the memory cells MC[1, 1] and MC[2, 1], respectively. Currents I_{MCref[1]} and I_{MCref[2]} flow from the wiring BLref to the transistors Tr12 of the memory cells MCref[1] and MCref[2], respectively.

Since the transistor Tr11 has a function of holding a potential of the node NM or the node NMref, the off-state current of the transistor Tr11 is preferably low. Thus, it is preferable to use an OS transistor, which has extremely low off-state current, as the transistor Tr11. This suppresses a change in the potential of the node NM or the node NMref, so that the operation accuracy can be increased. Furthermore, frequency of operations of refreshing the potential of the node NM or the node NMref can be low, which leads to a reduction in power consumption.

There is no particular limitation on the transistor Tr12, and for example, a Si transistor, an OS transistor, or the like can be used. In the case where an OS transistor is used as the transistor Tr12, the transistor Tr12 can be fabricated with the same manufacturing apparatus as that for the transistor Tr11, and accordingly manufacturing cost can be reduced. Note that the transistor Tr12 may be of either an n-channel type or a p-channel type.

The current source circuit CS is connected to the wirings BL[1] to BL[n] and the wiring BLref. The current source circuit CS has a function of supplying currents to the wirings BL[1] to BL[n] and the wiring BLref. Note that the value of the current supplied to the wirings BL[1] to BL[n] may be different from that of the current supplied to the wiring BLref. Here, the current supplied from the current source circuit CS to the wirings BL[1] to BL[n] is denoted by I_{C}, and the current supplied from the current source circuit CS to the wiring BLref is denoted by I_{Cref}.

The current mirror circuit CM includes wirings IL[1] to IL[n] and a wiring ILref. The wirings IL[1] to IL[n] are connected to the wirings BL[1] to BL[n], respectively, and the wiring ILref is connected to the wiring BLref. Here, a connection portion between the wirings IL[1] and BL[1] to a connection portion between the wirings IL[n] and BL[n] are referred to as nodes NP[1] to NP[n], respectively. Furthermore, a connection portion between the wiring ILref and the wiring BLref is referred to as a node NPref.

The current mirror circuit CM has a function of flowing a current I_{CM} corresponding to the potential of the node NPref to the wiring ILref and a function of flowing this current I_{CM} also to the wirings IL[1] to IL[n]. In the example illustrated in FIG. 12. the current I_{CM} is discharged from the wiring BLref to the wiring ILref, and the current I_{CM} is discharged from the wirings BL[1] to BL[n] to the wirings IL[1] to IL[n]. Furthermore, currents flowing from the current mirror circuits CM to the cell array CA through the wirings BL[1] to BL[n] are denoted by I_{B}[1] to I_{B}[n]. respectively. Furthermore, a current flowing from the current mirror circuit CM to the cell array CA through the wiring BLref is denoted by I_{Bref}.

The circuit WDD is connected to wirings WD[1] to WD[n] and the wiring WDref. The circuit WDD has a function of supplying a potential corresponding to the first data stored in the memory cells MC to the wirings WD[1] to WD[n]. The circuit WDD also has a function of supplying a potential corresponding to the reference data stored in the memory cell MCref to the wiring WDref. The circuit WLD is connected to wirings WL[1] to WL[m]. The circuit WLD has a function of supplying a signal for selecting the memory cell MC or MCref to which data is to be written to any of the wirings WL[1] to WL[m]. The circuit CLD is connected to the wirings RW[1] to RW[m]. The circuit CLD has a function of supplying a potential corresponding to the second data to the wirings RW[1] to RW[m].

The offset circuit OFST is connected to the wirings BL[1] to BL[n] and wirings OL[1] to OL[n]. The offset circuit OFST has a function of detecting the amount of currents flowing from the wirings BL[1] to BL[n] to the offset circuit OFST and/or the amount of a change in the currents flowing from the wirings BL[1] to BL[n] to the offset circuit OFST. The offset circuit OFST also has a function of outputting a detection result to the wirings OL[1] to OL[n]. Note that the offset circuit OFST may output a current corresponding to the detection result to the wiring OL, or may convert the current corresponding to the detection result into a voltage to output the voltage to the wiring OL. The currents flowing between the cell array CA and the offset circuit OFST are denoted by I_{α}[1] to I_{α}[n].

FIG. 14 illustrates a configuration example of the offset circuit OFST. The offset circuit OFST illustrated in FIG. 14 includes circuits OC[1] to OC[n]. Furthermore, the circuits OC[1] to OC[n] each include a transistor Tr21, a transistor Tr22, a transistor Tr23, a capacitor C21, and a resistor R1. Connection relations of the elements are as illustrated in FIG. 14. Note that a node connected to a first electrode of the capacitor C21 and a first terminal of the resistor R1 is referred to as a node Na. In addition, a node connected to a second electrode of the capacitor C21, one of a source and a drain of the transistor Tr21, and a gate of the transistor Tr22 is referred to as a node Nb.

A wiring VrefL has a function of supplying a potential Vref, a wiring VaL has a function of supplying a potential Va, and a wiring VbL has a function of supplying a potential Vb. Furthermore, a wiring VDRL, has a function of supplying a potential VDD, and a wiring VSSL has a function of supplying a potential VSS. Here, the case where the potential VDD is a high power supply potential and the potential VSS is a low power supply potential is described. Furthermore, a wiring RST has a function of supplying a potential for controlling the conduction state of the transistor Tr21. The transistor Tr22, the transistor Tr23, the wiring VDDL, the wiring VSSL, and the wiring VbL form a source follower circuit.

Next, an operation example of the circuits OC[1] to OC[n] is described. Note that although an operation example of the circuit OC[1] is described here as a typical example, the circuits OC[2] to OC[n] can be operated in a similar manner. First, when a first current flows to the wiring BL[1], the potential of the node Na becomes a potential corresponding to the first current and the resistance value of the resistor R1. At this time, the transistor Tr21 is brought into an on state, and thus the potential Va is supplied to the node Nb. Then, the transistor Tr21 is brought into an off state.

Next, when a second current flows to the wiring BL[1], the potential of the node Na becomes a potential corresponding to the second current and the resistance value of the resistor R1. At this time, since the transistor Tr21 is in an off state and the node Nb is in a floating state, the potential of the node Nb is changed owing to capacitive coupling, following the change in the potential of the node Na. Here, when the amount of change in the potential of the node Na is ΔV_{Na} and the capacitive coupling coefficient is 1, the potential of the node Nb is Va+ΔV_{Na}. In addition, when the threshold voltage of the transistor Tr22 is Vₜₕ, a potential of Va+ΔV_{Na}−Vₜₕ is output from the wiring OL[1]. Here, when Va=Vₜₕ, the potential ΔV_{Na} can be output from the wiring OL[1].

The potential ΔV_{Na} is determined by the amount of change from the first current to the second current, the resistor R1, and the potential Vref. Here, since the resistor R1 and the potential Vref are known, the amount of change in the current flowing to the wiring 131. can be found from the potential ΔV_{Na}.

A signal corresponding to the amount of current and/or the amount of change in the current detected by the offset circuit OFST as described above is input to the activation function circuit ACTV through the wirings OL[1] to OL[n].

The activation function circuit ACTV is connected to the wirings OL[1] to OL[n] and wirings NIL[1] to NIL[n]. The activation function circuit ACTV has a function of performing an operation for converting the signal input from the offset circuit OFST in accordance with the activation function defined in advance. As the activation function, for example, a sigmoid function, a tanh function, a softmax function, a ReLU function, a threshold function, or the like can be used. The signal converted by the activation function circuit ACTV is output as output data to the wirings NIL[1] to NIL[n].

<Operation Example of Semiconductor Device>

With the above semiconductor device MAC, the product-sum operation of the first data and the second data can be performed. An operation example of the semiconductor device MAC at the time of performing the product-sum operation is described below.

FIG. 15 is a timing chart showing the operation example of the semiconductor device MAC. FIG. 15 shows changes in the potentials of the wiring WL[1], the wiring WL[2], the wiring WD[1], the wiring WDref, the node NM[1, 1], the node NM[2, 1], the node NMref[1], the node NMref[2], the wiring RW[1], and the wiring RW[2] in FIG. 13 and changes in the values of the currents I_{B}[1] to I_{α}[1] and I_{Bref}. The currents I_{B}[1] to I_{α}[1] correspond to a total of the currents flowing from the wiring BL[1] to the memory cells MC[1, 1] and MC[2, 1].

No that although an operation is described with a focus on the memory cells MC[1, 1] and MC[2, 1] and the memory cells MCref[1] and MCref[2] illustrated in FIG. 13 as typical examples, the other memory cells MC and other memory cells MCref can also be operated in a similar manner.

[Storage of First Data]

First, during a period from Times T01 to T02, the potential of the wiring WL[1] becomes a high level, the potential of the wiring WD[1] becomes a potential greater than a ground potential (GND) by V_{PR}−V_{W[1, 1]}, and the potential of the wiring WDref becomes a potential greater than the ground potential by V_{PR}. Furthermore, the potentials of the wiring RW[1] and the wiring RW[2] are reference potentials (REFP). Note that the potential V_{W[1, 1]} is the potential corresponding to the first data stored in the memory cell MC[1, 1]. In addition, the potential V_{PR} is the potential corresponding to the reference data. Thus, the transistors Tr11 included in the memory cell MC[1, 1] and the memory cell MCref[1] are turned on, and the potentials of the node NM[1, 1] and the node NMref[1] become V_{PR}−V_{W[1, 1]} and V_{PR}, respectively.

In this case, a current I_{MC[1, 1], 0} flowing from the wiring BL[1] to the transistor Tr12 in the memory cell MC[1, 1] can be expressed by a formula shown below. Here, k is a constant determined by the channel length, the channel width, the mobility, the capacitance of a gate insulating film, and the like of the transistor Tr12. Furthermore, Vₜₕ is a threshold voltage of the transistor Tr12.

I_{MC[1, 1], 0}=k(V_{PR}−V_{W[1, 1]}−Vₜₕ)² (E1)

Furthermore, a current I_{MCref[1], 0} flowing from the wiring BLref to the transistor Tr12 in the memory cell MCref[1] can be expressed by a formula shown below.

I_{MCref[1], 0}=k(V_{PR}−Vₜₕ)² (E2)

Next, during a period from Times T02 to T03, the potential of the wiring WL[1] becomes a low level. Consequently, the transistors Tr11 included in the memory cell MC[1, 1] and the memory cell MCref[1] are turned off, and the potentials of the node NM[1, 1] and the node NMref[1] are held.

As described above, an OS transistor is preferably used as the transistor Tr11. This can suppress the leakage current of the transistor Tr11, so that the potentials of the node NM[1, 1] and the node NMref[1] can be accurately held.

Next, during a period from Times T03 to T04, the potential of the wiring WL[2] becomes the high level, the potential of the wiring WD[1] becomes a potential greater than the ground potential by V_{PR}−V_{W[2, 1]}, and the potential of the wiring WDref becomes a potential greater than the ground potential by V_{PR}. Note that the potential V_{W[2, 1]} is a potential corresponding to the first data stored in the memory cell MC[2, 1]. Thus, the transistors Tr11 included in the memory cell MC[2, 1] and the memory cell MCref[2] are brought into an on state, and the potentials of the node NM[2, 1] and the node NMref[2] become V_{PR}−V_{W[2, 1]} and V_{PR}, respectively.

Here, a current I_{MC[2, 1], 0} flowing from the wiring BL[1] to the transistor Tr12 in the memory cell MC[2, 1] can be expressed by a formula shown below

I_{MC[2, 1], 0}=k(V_{PR}−V_{W[2, 1]}−Vₜₕ)² (E3)

Furthermore, a current I_{MCref[2], 0} flowing from the wiring BLref to the transistor Tr12 in the memory cell MCref[2] can be expressed by a formula shown below.

I_{MCref[2], 0}=k(V_{PR}−Vₜₕ)² (E4)

Next, during a period from Times T04 to T05, the potential of the wiring WL[2] becomes the low level. Consequently, the transistors Tr11 included in the memory cell MC[2, 1] and the memory cell MCref[2] are brought into an off state, and the potentials of the node NM[2, 1] and the node NMref[2] are held.

Through the above operation, the first data is stored in the memory cells MC[1, 1] and MC[2, 1], and the reference data is stored in the memory cells MCref[1] and MCref[2].

Here, currents flowing to the wiring BL[1] and the wiring BLref during the period from Times T04 to T05 are considered. The current is supplied from the current source circuit CS to the wiring BLref. The current flowing through the wiring BLref is also discharged to the current mirror circuit CM and the memory cells MCref[1] and MCref[2]. A formula shown below holds where I_{Cref} is the current supplied from the current source circuit CS to the wiring BLref and I_{CM, 0} is the current discharged from the wiring BLref to the current mirror circuit CM.

I_{Cref}−I_{CM, 0}=I_{MCref[1], 0}+I_{MCref[2], 0} (E5)

The current from the current source circuit CS is supplied to the wiring BL[1]. The current flowing through the wiring BL[1] is also discharged to the current mirror circuit CM and the memory cells MC[1, 1] and MC[2, 1]. Furthermore, the current flows from the wiring BL[1] to the offset circuit OFST. A formula shown below holds where I_{C, 0} is the current supplied from the current source circuit CS to the wiring BL[1] and I_{α, 0} is the current flowing from the wiring BL[1] to the offset circuit OFST.

I_{C}−I_{CM, 0}=I_{MC[1, 1], 0}+I_{MC[2, 1], 0}+I_{α, 0} (E6)

[Product-Sum Operation of First Data and Second Data]

Next, during a period from Times T05 to T06. the potential of the wiring RW[1] becomes a potential greater than the reference potential by V_{X[1]}. At this time, the potential V_{X[1]} is supplied to the capacitors C11 in the memory cells MC[1, 1] and the memory cell MCref[1], so that the potentials of the gates of the transistors Tr12 increase owing to capacitive coupling. Note that the potential V_{X[1]} is the potential corresponding to the second data supplied to the memory cell MC[1, 1] and the memory cell MCref[1].

The amount of change in the potential of the gate of the transistor Tr12 corresponds to the value obtained by multiplying the amount of change in the potential of the wiring RW by a capacitive coupling coefficient determined by the memory cell configuration. The capacitive coupling coefficient is calculated on the basis of the capacitance of the capacitor C11, the gate capacitance of the transistor Tr12, the parasitic capacitance, and the like. In the following description, for convenience, the amount of change in the potential of the wiring RW is equal to the amount of change in the potential of the gate of the transistor Tr12, that is, the capacitive coupling coefficient is set to 1. In practice, the potential V_{X} can be determined in consideration of the capacitive coupling coefficient.

When the potential V_{X[1]} is supplied to the capacitors C11 in the memory cell MC[1] and the memory cell MCref[1], the potentials of the node NM[1] and the node NMref[1] each increase by V_{X[1]}.

Here, a current I_{MC[1, 1], 1} flowing from the wiring BL[1] to the transistor Tr12 in the memory cell MC[1, 1] during the period from Times T05 to T06 can be expressed by a formula shown below.

I_{MC[1, 1], 1}=k(V_{PR}−V_{W[1, 1]}+V_{X[1]}−Vₜₕ)² (E7)

Thus, when the potential V_{X[1]} is supplied to the wiring RW[1], the current flowing from the wiring BL[1] to the transistor Tr12 in the memory cell MC[1, 1] increases by ΔI_{MC[1, 1]}=I_{MC[1, 1], 1}−I_{MC[1, 1], 0}.

In addition, a current I_{MCref[1], 1} flowing from the wiring BLref to the transistor Tr12 in the memory cell MCref[1] during the period from Times T05 to T06 can be expressed by a formula shown below

I_{MCref[1], 1}=k(V_{PR}+V_{X[1]}−Vₜₕ)² (E8)

Thus, when the potential V_{X[1]} is supplied to the wiring RW[1], the current flowing from the wiring BLref to the transistor Tr12 in the memory cell MCref[1] increases by ΔI_{MCref[1]}=I_{MCref[1], 1}−I_{MCref[1], 0}.

Furthermore, currents flowing to the wiring BL[1] and the wiring BLref are considered. A current I_{Cref} is supplied from the current source circuit CS to the wiring BLref. The current flowing through the wiring BLref is also discharged to the current mirror circuit CM and the memory cells MCref[1] and MCref[2]. A formula shown below holds where I_{CM, 1} is the current discharged from the wiring BLref to the current mirror circuit CM.

I_{Cref}−I_{CM, 1}=I_{MCref[1], 1}+I_{MCref[2], 0} (E9)

The current I_{C} from the current source circuit CS is supplied to the wiring BL[1]. The current flowing through the wiring BL[1] is also discharged to the current mirror circuit CM and the memory cells MC[1, 1] and MC[2, 1]. Furthermore, the current flows from the wiring BL[1] to the offset circuit OFST. A formula shown below holds where I_{α, 1} is the current flowing from the wiring BL[1] to the offset circuit OFST.

I_{C}−I_{CM, 1}=I_{MC[1, 1], 1}+I_{MC[2, 1], 1}+I_{α, 1} (E10)

In addition, from Formula (E1) to Formula (E10), a difference between the current I_{α, 0} and the current L_{α, 0} (differential current ΔI_{α}) can be expressed by a formula shown below.

ΔI_{α}=I_{α, 0}−I_{α, 1}=2kV_{W[1, 1]}V_{X[1]} (E11)

Thus, the differential current ΔI_{α} is a value corresponding to the product of the potentials V_{W[1, 1]} and V_{X[1]}.

After that, during a period from Times T06 to T07, the potential of the wiring RW[1] becomes the ground potential, and the potentials of the node NM[1, 1] and the node NMref[1] become similar to the potentials thereof during the period from Times T04 to T05.

Next, during a period from Times T07 to T08, the potential of the wiring RW[1] becomes the potential greater than the reference potential by V_{X[1]}, and the potential of the wiring RW[2] becomes a potential greater than the reference potential by V_{X[2]}. Accordingly, the potential V_{X[1]} is supplied to the capacitors C11 in the memory cell MC[1, 1] and the memory cell MCref[1], and the potentials of the node NM[1, 1] and the node NMref[1] each increase by V_{X[1]} due to capacitive coupling. Furthermore, the potential V_{X[2]} is supplied to the capacitors C11 in the memory cell MC[2, 1] and the memory cell MCref[2], and the potentials of the node NM[2, 1] and the node NMref[2] each increase by V_{X[2]} due to capacitive coupling.

Here, the current I_{MC[2, 1], 1} flowing from the wiring BL[1] to the transistor Tr12 in the memory cell MC[2, 1] during the period from Times T07 to T08 can be expressed by a formula shown below.

I_{MC[2, 1], 1}=k(V_{PR}−V_{W[2, 1]}+V_{X[2]}−Vₜₕ)² (E12)

Thus, when the potential V_{X[2]} is supplied to the wiring RW[2], the current flowing from the wiring BL[1] to the transistor Tr12 in the memory cell MC[2, 1] increases by ΔI_{MC[2,1}]=I_{MC[2, 1], 1}−I_{MC[2, 1], 0}.

Here, a current I_{MCref[2], 1} flowing from the wiring BLref to the transistor Tr12 in the memory cell MCref[2] during the period from Times T05 to T06 can be expressed by a formula shown below.

I_{MCref[2], 1}=k(V_{PR}+V_{X[2]}−Vₜₕ)² (E13)

Thus, when the potential V_{X[2]} is supplied to the wiring RW[2], the current flowing from the wiring BLref to the transistor Tr12 in the memory cell MCref[2] increases by ΔI_{MCref[2]}=I_{MCref[2], 1}−I_{MCref[2], 0}.

Furthermore, currents flowing to the wiring BL[1] and the wiring BLref are considered. The current I_{Cref} is supplied from the current source circuit CS to the wiring BLref. The current flowing through the wiring BLref is also discharged to the current mirror circuit CM and the memory cells MCref[1] and MCref[2]. A formula shown below holds where I_{CM, 2} is the current discharged from the wiring BLref to the current mirror circuit CM.

I_{Cref}−I_{CM, 2}=I_{MCref[1], 1}+I_{MCref[2], 1} (E14)

The current I_{C} from the current source circuit CS is supplied to the wiring BL[1]. The current flowing through the wiring BL[1] is also discharged to the current mirror circuit CM and the memory cells MC[1, 1] and MC[2, 1]. Furthermore, the current flows from the wiring BL[1] to the offset circuit OFST. A formula shown below holds where I_{α, 2} is the current flowing from the wiring BL[1] to the offset circuit OFST.

_{C}−I_{CM, 2}=I_{MC[1, 1], 1}+I_{MC[2, 1], 1}+I_{α, 2} (E15)

In addition, from Formula (E1) to Formula (E8) and Formula (E12) to Formula (E15), a difference between the current I_{α, 0} and the current I_{α, 2} (differential current ΔI_{α}) can be expressed by a formula shown below.

ΔI_{α}=I_{α, 0}−I_{α, 2}=2k(V_{W[1, 1]}V_{X[1]}+V_{W[2, 1]}V_{X[2]}) (E16)

Thus, the differential current ΔI_{α} is a value corresponding to a result of the sum of the product of the potential V_{W[1, 1]} and the potential V_{X[1]} and the product of the potential V_{W[2, 1]} and the potential V_{X[2]}.

After that, during a period from Times T08 to T09, the potentials of the wirings RW[1] and RW[2] become the ground potential, and the potentials of the nodes NM[1, 1] and NM[2, 1] and the nodes NMref[1] and NMref[2] become similar to the potentials thereof during the period from Times T04 to T05.

As represented by Formula (E9) and Formula (E16), the differential current ΔI_{α} input to the offset circuit OFST is a value corresponding to a result of the sum of the products of the potentials V_{X} corresponding to the first data (weight) and the potentials V_{W} corresponding to the second data (input data). Thus, measurement of the differential current ΔI_{α} with the offset circuit OFST gives the result of the product-sum operation of the first data and the second data.

Note that although the memory cells MC[1, 1] and MC[2, 1] and the memory cells MCref[1] and MCref[2] are focused on in the above description, the number of the memory cells MC and MCref can be set freely. The differential current ΔI_{α} can be expressed by a formula shown below in the case where the number m of rows of the memory cell MC and the memory cell MCref is a given number.

ΔI_{α}=2kΣᵢV_{W[i, 1]}V_{X[i]} (E17)

Furthermore, when the number n of columns of the memory cell MC and the memory cell MCref is increased, the number of product-sum operations executed in parallel can be increased.

The product-sum operation of the first data and the second data can be performed using the semiconductor device MAC as described above. Note that the use of the configuration of the memory cell MC and the memory cell MCref in FIG. 13 allows the product-sum operation circuit to be formed of a smaller number of transistors. Accordingly, the circuit scale of the semiconductor device MAC can be reduced.

In the case where the semiconductor device MAC is used for the operation in the neural network, the number in of rows of the memory cells MC can correspond to the number of pieces of input data supplied to one neuron and the number n of columns of the memory cells MC can correspond to the number of neurons. For example, the case where a product-sum operation using the semiconductor device MAC is performed in the middle layer HL in FIG. 11(A) is considered. In this case, the number m of rows of the memory cells MC can be set to the number of pieces of input data supplied from the input layer IL (the number of neurons in the input layer IL), and the number n of columns of the memory cells MC can be set to the number of neurons in the middle layer HL.

Note that there is no particular limitation on the configuration of the neural network for which the semiconductor device MAC is used. For example, the semiconductor device MAC can also be used for a convolutional neural network (CNN), a recurrent neural network (RNN), an autoencoder, a Boltzmann machine (including a restricted Boltzmann machine), or the like.

The product-sum operation of the neural network can be performed using the semiconductor device MAC as described above. Furthermore, the memory cell MC and the memory cell MCref illustrated in FIG. 13 are used for the cell array CA, which can provide an integrated circuit IC with improved operation accuracy, lower power consumption, or a reduced circuit scale.

This embodiment can be combined with the description of the other embodiments as appropriate.

### Embodiment 3

In this embodiment, examples of the portable information terminal described in the above embodiment will be described with reference to FIG. 16(A) to FIG. 16(D). One embodiment of the present invention can be applied to portable electronic devices, information terminals such as a smartphone and a notebook personal computer.

A portable information terminal 2910 illustrated in FIG. 16(A) includes a housing 2911, a display portion 2912, a microphone 2917, a speaker portion 2914, a camera 2913, an external connection portion 2916, operation switches 2915, and the like. A display panel and a touch screen that use a flexible substrate are provided in the display portion 2912. The information terminal 2910 also includes an antenna, a battery, and the like inside the housing 2911. The information terminal 2910 can be used as, for example, a smartphone, a mobile phone, a tablet information terminal, a tablet personal computer, or an e-book reader.

A portable notebook personal computer 2920 illustrated in FIG. 16(B) includes a housing 2921, a display portion 2922, a keyboard 2923, a pointing device 2924, and the like. The notebook personal computer 2920 also includes an antenna, a battery, and the like inside the housing 2921.

Note that one embodiment of the present invention can be applied not only to a portable information terminal but also to autonomous moving vehicles such as an automobile and a robot.

A robot 2100 illustrated in FIG. 16(C) includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The above semiconductor device can be used for the arithmetic device 2110, the illuminance sensor 2101, the upper camera 2103, the display 2105, the lower camera 2106, the obstacle sensor 2107, and the like of the robot 2100.

The microphone 2102 has a function of detecting a speaking voice of a user, an environmental sound, and the like. The speaker 2104 has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel.

The upper camera 2103 and the lower camera 2106 each have a function of taking an image of the surroundings of the robot 2100. The obstacle sensor 2107 can detect whether an obstacle exists or not in the direction where the robot 2100 advances with the moving mechanism 2108. The robot 2100 can move safely by recognizing the surrounding environment with the upper camera 2103, the lower camera 2106, and the obstacle sensor 2107.

A flying object 2120 illustrated in FIG. 16(D) includes an arithmetic device 2121, propellers 2123, and a camera 2122 and has a function of flying autonomously.

The above semiconductor device can be used for the arithmetic device 2121 and the camera 2122 of the flying object 2120.

FIG. 16(D) is an external view illustrating an example of an automobile. An automobile 2980 includes a camera 2981 and the like. The automobile 2980 also includes various kinds of sensors and the like such as an infrared radar, a millimeter wave radar, and a laser radar. The automobile 2980 judges traffic conditions therearound such as the presence of a guardrail 1201 and a pedestrian with analyzing an image taken by the camera 2981, and thus can perform automatic driving.

This embodiment can be combined with the description of the other embodiments as appropriate.

<Notes on Description of This Specification and the Like>

Ordinal numbers such as “first,” “second,” and “third” in this specification and the like are used in order to avoid confusion among components. Thus, the terms do not limit the number of components. In addition, the terms do not limit the order of components.

In this specification and the like, components are classified on the basis of the functions and shown as blocks independent of each other in block diagrams. However, in an actual circuit or the like, it may be difficult to separate components on the basis of the functions, and one circuit may be associated with a plurality of functions or several circuits may be associated with one function. Therefore, blocks in the block diagrams are not limited by any of the components described in the specification, and can be differently determined as appropriate depending on situations.

Note that in the drawings, the same elements, elements having similar functions, elements formed of the same material, elements formed at the same time, or the like are sometimes denoted by the same reference numerals, and repeated description thereof is omitted in some cases.

In this specification and the like, one of a source and a drain is denoted by “one of a source and a drain” (or a first electrode or a first terminal) and the other of the source and the drain is denoted by “the other of the source and the drain” (or a second electrode or a second terminal) in the description of the connection relation of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation.

In this specification and the like, voltage and potential can be interchanged with each other as appropriate. The voltage refers to a potential difference from a reference potential, and when the reference potential is a ground potential, for example, the voltage can be rephrased into the potential. The ground potential does not necessarily mean 0 V. Note that potentials are relative values, and the potential applied to a wiring or the like is changed depending on the reference potential, in some cases.

In this specification and the like, a switch has a function of determining whether to flow current or not by being in a conduction state (on state) or a non-conduction state (off state). Alternatively, a switch has a function of selecting and switching a current path.

As an example of a switch, an electrical switch or a mechanical switch can be used. That is, a switch can be any element capable of controlling current, and is not limited to a certain element.

Note that in the case where a transistor is used as a switch, the “conduction state” of the transistor refers to a state in which a source and a drain of the transistor can be regarded as being electrically short-circuited. In addition, the “non-conduction state” of the transistor refers to a state in which the source and the drain of the transistor can be regarded as being electrically disconnected. Note that in the case where a transistor operates just as a switch, there is no particular limitation on the polarity (conductivity type) of the transistor.

In this specification and the like, the expression “A and B are connected” means the case where A and B are electrically connected as well as the case where A and B are directly connected. Here, the expression “A and B are electrically connected” means the case where electric signals can be transmitted and received between A and B when an object having any electric action exists between A and B.

### REFERENCE NUMERALS

C11: capacitor,
C21: capacitor,
NN1: in the figure,
NN2: in the figure,
R1: resistor,
T01-T02: time,
T02-T03: time,
T03-T04: time,
T04-T05: time,
T05-T06: time,
T06-T07: time,
T07-T08: time,
T08-T09: time,
Tr11: transistor,
Tr12: transistor,
Tr21: transistor,
Tr22: transistor,
Tr23: transistor,
10: problem solving system,
10A: problem solving system,
12: Tr,
20: portable information terminal,
21: input portion,
22: input operation portion,
23: signal transmitting/receiving portion,
24: output operation portion,
25: output portion,
26: neural network circuit,
27: neural network circuit,
28: judgement circuit,
30: data server,
1201: guardrail,
2100: robot,
2101: illuminance sensor,
2102: microphone,
2103: upper camera,
2104: speaker,
2105: display,
2106: lower camera,
2107: obstacle sensor,
2108: moving mechanism,
2110: arithmetic device,
2120: flying object,
2121: arithmetic device,
2122: camera,
2123: propeller,
2910: information terminal,
2911: housing,
2912: display portion,
2913: camera,
2914: speaker portion,
2915: operation switch,
2916: external connection portion,
2917: microphone,
2920: notebook personal computer,
2921: housing,
2922: display portion,
2923: keyboard,
2924: pointing device,
2980: car,
2981: camera

1. A portable information terminal comprising:
an input operation portion;
a signal transmitting/receiving portion; and
an output operation portion,
wherein the input operation portion comprises a first neural network circuit configured to generate first data on the basis of input information,
wherein the first neural network circuit is configured to learn a plurality of pieces of input information as learning data,
wherein the signal transmitting/receiving portion is configured to transmit the first data to a data server and receive information data from the data server in response to the first data,
wherein the output operation portion comprises a second neural network circuit configured to learn the information data as learning data, and
wherein the second neural network circuit is configured to generate output information on the basis of the learning.

2. The portable information terminal according to claim 1,
wherein the input operation portion comprises a judgement circuit,
wherein the judgement circuit is configured to store judgement data, and
wherein the input operation portion is configured to compare the first data and the judgement data and stop an operation of the signal transmitting/receiving portion in accordance with a result of the comparison.

3. The portable information terminal according to claim 1,
wherein the first neural network circuit and the second neural network circuit each comprise a product-sum operation circuit.

4. The portable information terminal according to claim 1,
wherein the product-sum operation circuit comprises a memory element,
wherein the memory element comprises a transistor, and
wherein the transistor comprises an oxide semiconductor in a semiconductor layer comprising a channel formation region.

5. A problem solving system comprising:
a portable information terminal comprising an input operation portion, a signal transmitting/receiving portion, and an output operation portion; and
a data server that stores information data,
wherein the input operation portion comprises a first neural network circuit configured to generate first data on the basis of input information,
wherein the first neural network circuit is configured to learn a plurality of pieces of input information as learning data,
wherein the signal transmitting/receiving portion is configured to transmit the first data to the data server and receive the information data from the data server in response to the first data,
wherein the output operation portion comprises a second neural network circuit configured to learn the information data as learning data, and
wherein the second neural network circuit is configured to generate output information on the basis of the learning.

6. The problem solving system according to claim 5,
wherein the input operation portion comprises a judgement circuit,
wherein the judgement circuit is configured to store judgement data, and
wherein the input operation portion is configured to compare the first data and the judgement data and stop an operation of the signal transmitting/receiving portion in accordance with a result of the comparison.

7. The problem solving system according to claim 5,
wherein the first neural network circuit and the second neural network circuit each comprise a product-sum operation circuit.

8. The problem solving system according to claim 5,
wherein the product-sum operation circuit comprises a memory element,
wherein the memory element comprises a transistor, and
wherein the transistor comprises an oxide semiconductor in a semiconductor layer comprising a channel formation region.
